(19) United States
(12) Patent Application Publication
(10) Pub. No.: US 2014/0230992 A1
(43) Pub. Date: Aug. 21, 2014

(54) QUANTUM DOT-WAVELENGTH CONVERTER, MANUFACTURING METHOD OF THE SAME AND LIGHT EMITTING DEVICE INCLUDING THE SAME

(71) Applicant: SAMSUNG ELECTRONICS CO., LTD., Suwon-si (KR)

(72) Inventors: Jae Il KIM, Seoul (KR); Bae Kyun KIM, Seongnam (KR); Dong Hyun CHO, Gimhae (KR); Kyoung Soon PARK, Suwon (KR); In Hyung LEE, Seoul (KR)

(73) Assignee: SAMSUNG ELECTRONICS CO., LTD., Suwon-si (KR)

(21) Appl. No.: 14/262,092

(22) Filed: Apr. 25, 2014

Related U.S. Application Data
(62) Division of application No. 12/397,102, filed on Mar. 3, 2009.

(30) Foreign Application Priority Data
Sep. 3, 2008 (KR) 10-2008-0086984

(51) Int. Cl. H01L 33/50

(52) U.S. Cl. CPC H01L 33/502
USPC 156/67

(57) ABSTRACT

There is provided a quantum dot wavelength converter including a quantum dot, which is optically stable without any change in an emission wavelength and improved in emission capability. The quantum dot wavelength converter includes: a wavelength converting part including a quantum dot wavelength-converting excitation light and generating a wavelength-converted light and a dispersive medium dispersing the quantum dot; and a sealer sealing the wavelength converting part.

### CROSS-REFERENCE TO RELATED APPLICATIONS

This application claims the priority of Korean Patent Application No. 2008-086984 filed on Sep. 3, 2008, in the Korean Intellectual Property Office, the disclosure of which is incorporated herein by reference.

### BACKGROUND OF THE INVENTION

1. Field of the Invention

The present invention relates to a quantum dot wavelength converter, a manufacturing method of the same, and a light emitting device including the quantum dot wavelength converter, and more particularly, to a quantum dot wavelength converter including a quantum dot, which is optically stable without any change in an emission wavelength band and improved in emission capability, a manufacturing method of the same, and a light emitting device employing the quantum dot wavelength converter to adjust an emission wavelength and emission intensity more simply.

2. Description of the Related Art

Quantum dots are a semiconductor material of a nano size and exhibit quantum confinement effects. The quantum dots generate stronger light in a narrow wavelength band than a general phosphor. The quantum dots emit light when excited electrons transition from a conduction band to a valence band. Even in the same material, the quantum dots have a wavelength varied according to size of particles. With a smaller size in quantum dots, the quantum dots emit light of a shorter wavelength. Thus, these quantum dots can be adjusted in size to obtain light of a desired wavelength range.

Quantum dots emit light even when an excitation wavelength is arbitrarily selected. Therefore, when several kinds of quantum dots are excited to one wavelength, light of various colors can be observed at one time. Also, the quantum dots transition only from a bottom vibration state of a conduction band to a bottom vibration state of a valence band, and thus have an emission wavelength in light of a substantially mono color.

Quantum dots are a nano crystal of a semiconductor material having a diameter of about 10 nm or less. To synthesize a nano crystal as a quantum dot, quantum dots may be prepared by vapor deposition such as metal organic chemical vapor deposition (MOCVD) or molecular beam epitaxy (MBE), or by chemical wetting in which a crystal is grown by adding a precursor into an organic solvent.

Through the chemical wetting, when a crystal is grown, an organic solvent is naturally applied on a quantum dot surface to serve as a dispersant, thereby regulating the growth the crystal. Thus, the chemical wetting enables the nano crystal to be controlled in uniformity of size and shape more easily and less expensively than the vapor deposition such as metal organic chemical vapor deposition (MOCVD) or molecular beam epitaxy (MBE).

The quantum dots prepared by the chemical wetting are not employed as an undiluted solution but a predetermined ligand is disposed around the quantum dots to ensure easy storage and use. The material used as the ligand of quantum dots may adopt, for example, trioctylphosphine oxide (TOPO). In a case where these quantum dots are utilized in a light emitting device, the quantum dots should be purified to remove the ligand before being added to a sealer such as resin.

The quantum dots when purified cause side effects such as less light emission, precipitation in a solution resulting from removal of ligand or change in an emission wavelength band due to surface oxidization. To solve these problems, the quantum dots are capped with an organic material or enclosed with a material having a bandgap bigger than the quantum dots.

However, a method of capping the quantum dots with an organic material or enclosing the quantum dots with a material of a bigger band gap raises a problem of efficiency in terms of process or costs. Therefore, there has been a call for developing a method of using quantum dots which are more stable and improved in emission capability.

### SUMMARY OF THE INVENTION

An aspect of the present invention provides a quantum dot wavelength converter including quantum dots which are optically stable without undergoing any change in an emission wavelength band and improved in emission capability, and a manufacturing method of the same.

Another aspect of the present invention provides a light emitting device employing a quantum dot wavelength converter to adjust an emission wavelength and emission intensity using the quantum dot wavelength converter.

According to an aspect of the present invention, there is provided a quantum dot wavelength converter including: a wavelength converting part including a quantum dot wavelength-converting excitation light and generating a wavelength-converted light and a dispersive medium dispersing the quantum dot; and a sealer sealing the wavelength converting part.

The quantum dot may include one of a Si-based nano crystal, a group II-VI compound semiconductor nano crystal, a group III-V compound semiconductor nano crystal, a group IV-VI compound nano crystal and a mixture thereof. The group II-VI compound semiconductor nano crystal may include one selected from a group consisting of CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HggZnTe, CdZnSeS, CdZnSeTe, CdZnSTe, CdHgSeS, CdHgSeTe, CdHgSTe, HgZnSeS, HgZnSeTe and HgZnSTe. The group III-V compound semiconductor nano crystal may include one selected from a group consisting of GaN, GaP, GaAs, AlN, Alp, AlAs, InN, InP, InAs, GaNP, GaNAs, GaPAs, AlNP, AlNAs, AlPAs, InNP, InNAs, InPAs, GaAlNP, GaAlNAs, GaAlPAs, GaInNP, GaInNAs, GaInPAs, InAlNP, InAlNAs, and InAlPAs. The IV-VI compound semiconductor nano crystal may be SbTe.

The dispersive medium may be a liquid. The dispersive medium may be one of epoxy resin and silicone.

The sealer may include silicone.

According to another aspect of the present invention, there is provided a method of manufacturing a quantum dot wavelength converter, the method including: dispersing a quantum dot wavelength-converting excitation light and generating a wavelength-converted light in a dispersive medium to prepare a wavelength converting part; and sealing the wavelength converting part with a sealer. The sealing may include stacking first and second sealing sheets; injecting the wavelength converting part into an area of the first and second sealing sheets; and heating around and thermally adhering the wavelength converting part of the first and second sealing sheets.

According to still another aspect of the present invention, there is provided a light emitting device including: a light emitting source; and a quantum dot wavelength converter disposed above the light emitting source in a light emitting direction, the quantum dot wavelength converter including: a wavelength converting part including a quantum dot wavelength-converting excitation light and generating a wavelength-converted light and a dispersive medium dispersing the quantum dot; and a sealer sealing the wavelength converting part. The light emitting source may be one of a light emitting diode and a laser diode.

The quantum dot wavelength converter may include a plurality of quantum dot wavelength converters. At least two out of the plurality of quantum dot wavelength converters each may include quantum dots capable of converting light emitted from the light source into light of a different wavelength. The light emitting source may emit blue light, out of the plurality of wavelength converting parts, a first quantum dot wavelength converter may emit red light, and out of the plurality of wavelength converting parts, a second quantum dot wavelength converter different from the first quantum dot wavelength converter may emit green light.

The light emitting device may further include: a groove including a bottom surface where the light emitting source is to be mounted and a side surface having a reflecting part formed thereon; and a supporter supporting the groove and having an electrode part electrically connected to the light emitting source. The groove may be sealed with the sealer. The sealer may include at least one selected from a group consisting of epoxy, silicone, acrylic polymer, glass, carbonate polymer and a mixture thereof.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 illustrates a quantum dot wavelength converter according to an exemplary embodiment of the invention;

FIGS. 2A to 2C illustrate a method of manufacturing a quantum dot wavelength converter according to an exemplary embodiment of the invention;

FIG. 3 illustrates a light emitting device including a quantum dot wavelength converter according to an exemplary embodiment of the invention; and

FIG. 4 illustrates a light emitting device including a quantum dot wavelength converter according to another exemplary embodiment of the invention.

### DETAILED DESCRIPTION OF THE PREFERRED EMBODIMENT

Exemplary embodiments of the present invention will now be described in detail with reference to the accompanying drawings. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference signs are used to designate the same or similar components throughout.

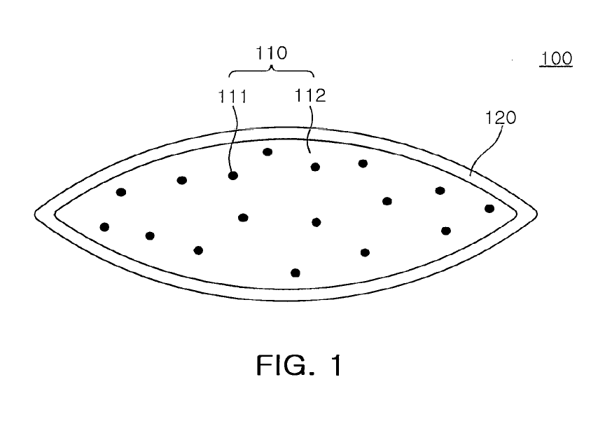

FIG. 1 illustrates a quantum dot wavelength converter according to an exemplary embodiment of the invention. The quantum dot wavelength converter 100 of the present embodiment includes a wavelength converting part 110 and a sealer 120. The wavelength converting part 110 includes quantum dots 111 wavelength-converting excitation light and generating wavelength-converted light and a dispersive medium 112 dispersing the quantum dots. The sealer 120 seals the wavelength converting part 110.

The quantum dot wavelength converter 100 emits light wavelength-converted from the quantum dots 111 (hereinafter, wavelength-converted light) when light incident from the outside (hereinafter, incident light) reaches the quantum dots 111. Therefore, the quantum dot wavelength converter 100 serves to change a wavelength of light by the quantum dots. Hereinafter, out of incident light, a portion of light having a shorter wavelength than an emission wavelength of the quantum dots ill is referred to as excitation light.

The quantum dots 111 are a luminous body of a nano size as described above and may be a semiconductor nano crystal. The quantum dots may employ a Si nano crystal, a group II-VI compound semiconductor nano crystal, a group III-V compound semiconductor nano crystal, a group IV-VI compound semiconductor nano crystal, which may be utilized alone or in combination according to the present embodiment.

Among these, the group II-VI compound semiconductor nano crystal may be one selected from adopt, CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HggZnTe, CdZnSeS, CdZnSeTe, CdZnSTe, CdHgSeS, CdHgSeTe, CdHgSTe, HgZnSeS, HgZnSeTe and HgZnSTe, but the present invention is not limited thereto.

Also, the group III-V compound semiconductor nano crystal may be one selected from GaN, GaP, GaAs, AlN, AlP, AlAs, InN, InP, InAs, GaNP, GaNAs, GaPAs, AlNP, AlNAs, AlPAs, InNP, InNAs, InPAs, GaAlNP, GaAlNAs, GaAlPAs, GaInNP, GaInNAs, GaInPAs, InAlNP, InAlNAs, and InAlPAs, but the present invention is not limited thereto.

Moreover, the group IV-VI compound semiconductor nano crystal may employ SbTe but the present invention is not limited thereto.

In the present embodiment, the quantum dots 111 are dispersed in the dispersive medium 112. The dispersive medium 112 may be a liquid. When the dispersive medium 112 as a liquid is mixed with the quantum dots 111 and sealed by the sealer 120, the dispersive medium 112, for example, is substantially in a state where a liquid is contained in a plastic pack. Thus, the dispersive medium 112 is not limited in shape and can be used and managed easily. The dispersive medium 12 may be formed of e.g., epoxy resin or silicone. The quantum dot wavelength converter 100 should receive the excitation light and emit the wavelength-converted light. Accordingly, the dispersive medium 112 may be formed of a material which is not discolored or changed by the excitation light.

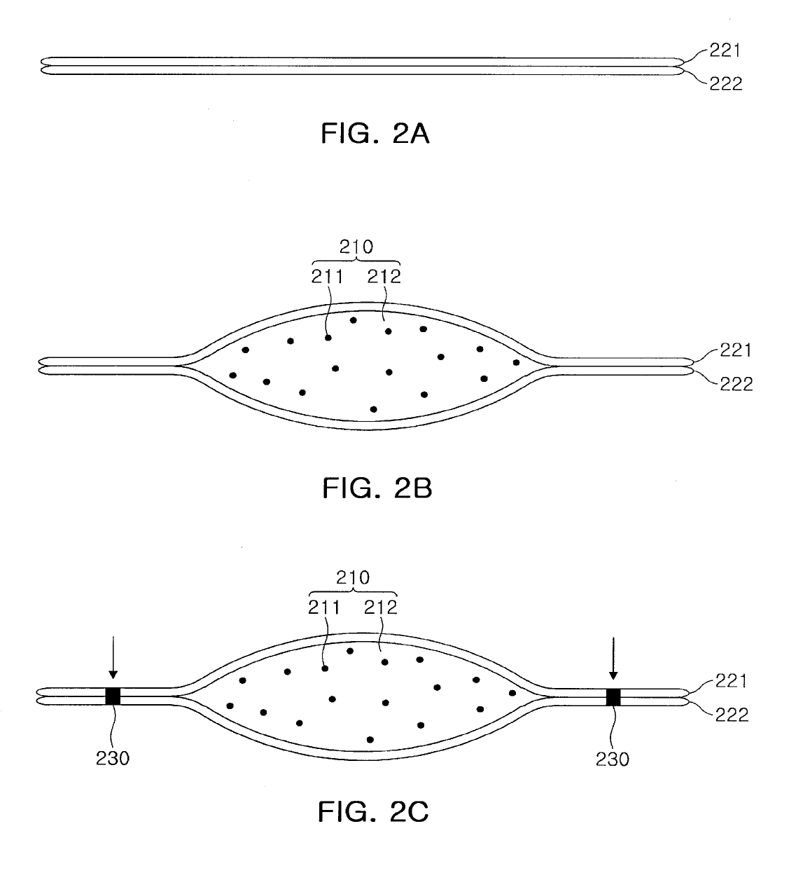

The sealer 120 sealing the wavelength converting part may utilize a kind of polymer pack that is not corroded by the wavelength converting part 110 where the quantum dots are dispersed. Moreover, the sealer 120 may adopt silicone. The polymer resin can be heated and adhered, and thus a polymer resin as a sheet can be employed as a sealer to provide a pack where the wavelength converting part 110 is located inside through thermal adhesion. A method of manufacturing the quantum dot wavelength converter 100 will be further described with reference to FIG. 2.

The quantum dots 111 are dispersed in the dispersive medium 112 in an undiluted liquid state, without being purified after synthesis and sealed by the sealer 120. Therefore, the quantum dots 111 exhibit high emission capability without suffering problems such as less light emission or change in emission wavelength in a purification process.

FIGS. 2A to 2C illustrate a method of manufacturing a quantum dot wavelength converter according to an exemplary embodiment of the invention.

According to another aspect of the present invention, in order to manufacture the quantum dot wavelength converter, quantum dots 211 are dispersed in a dispersive medium 212 to prepare a wavelength converting part 210. Then the wavelength converting part 210 is sealed by sealers 221 and 222.

The wavelength converting part 210 can be sealed by various methods. In the present embodiment, to seal the wavelength converting part 210, first, first and second sealing sheets 221 and 222 are stacked (refer to FIG. 2A). Here, the first sealing sheet 221 and the second sealing sheet 222 are only stacked but not adhered together.

Next, between the first and second sealing sheets 221 and 222, the wavelength converting part 210 is injected (see FIG. 2B). The first and second sealing sheets 221 and 222 are not adhered together, and thus after the wavelength converting part 210 is injected, peripheral portions 230 of the wavelength converting part 210 are heated and thermally adhered (see FIG. 2C). Therefore, the wavelength converting part 210 is disposed between the first sealing sheet 221 and the second sealing sheet 222 and the wavelength converting part 210 is sealed, thereby producing a quantum dot wavelength converter 200.

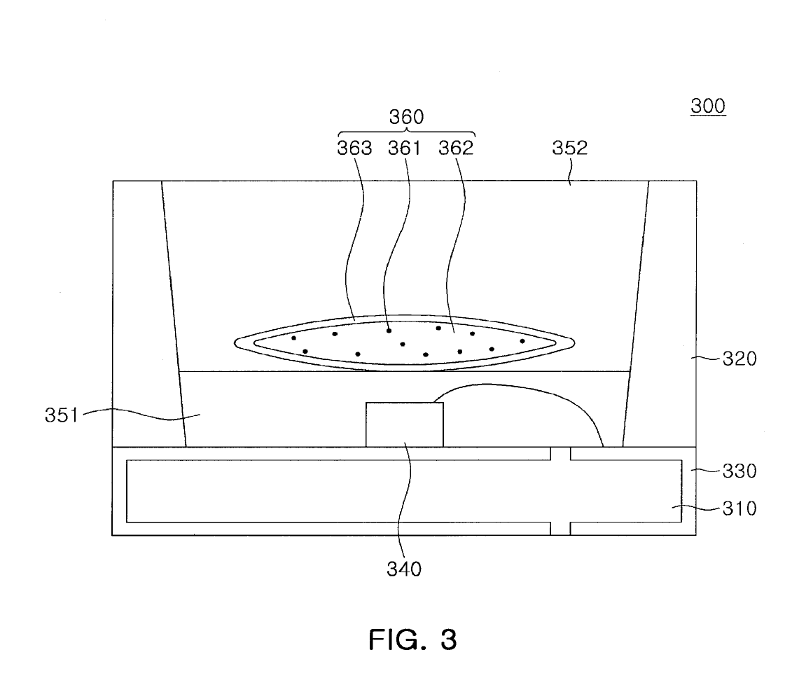

According to still another aspect of the present invention, a light emitting device includes a light emitting source and a quantum dot wavelength converter. FIG. 3 illustrates a light emitting device including a quantum dot wavelength converter according to an exemplary embodiment of the invention.

According to the present embodiment, the light emitting device 300 includes a light emitting source 340, and a quantum dot wavelength converter 360. The quantum dot wavelength converter 360 includes a wavelength converting part and a sealer 363 sealing the wavelength converting part. Here, the wavelength converting part includes quantum dots and a dispersive medium 362 dispersing the quantum dots 361.

Referring to FIG. 3, in the light emitting device 300 of the present embodiment, the light emitting source 340 includes a groove and a supporter 310. The groove includes a bottom surface where the light emitting source 340 is disposed and a side surface where a reflecting part 320 is formed. The supporter 310 supports the groove and has an electrode part 330 electrically connected to the light source. The electrode part 330 is formed of two electrode parts having different polarities from each other and thus electrically insulated from each other.

The light emitting source 340 may be one of a light emitting diode (LED) and a laser diode. The light emitting source 340 may emit light having a shorter wavelength than an emission wavelength of the quantum dots 361 of the quantum dot wavelength converter 360. The light emitting source 340 may adopt, for example, a blue LED. A gallium nitride LED emitting blue light of a wavelength of 420 to 480 nm may be employed.

The supporter 310 has a terminal electrode 330 formed thereon to be connected to the light emitting source 340 through a wire. A first encapsulant 351 filled with an encapsulating material is formed on the light emitting source 340 to encapsulate the light emitting source 340. Also, when the quantum dot wavelength converter 360 is positioned on the first encapsulant 351, a second encapsulant 352 may be further formed to protect and fix the first encapsulant 351. The encapsulating material may employ at least one of epoxy, silicon, acrylic polymer, glass, carbonate polymer and a mixture thereof.

The quantum dot wavelength converter 360 may include the quantum dots adequately according to a wavelength of desired light from the light emitting device 300. In the drawing of the present invention, the quantum dot wavelength converter 360 is illustrated to be located on the first encapsulant 351. However, the quantum dot wavelength converter 360 may be configured to surround a surface of the light emitting source 340 without employing the first encapsulant 351. The quantum dot wavelength converter 360 may be configured variously as long as the light emitted from the light emitting source 340 is incident thereon and can be wavelength-converted.

Here, when the light emitting source 340 emits blue light and the quantum dots 361 of the quantum dot wavelength converter 360 emit yellow light, the light emitting device 300 may emit white light.

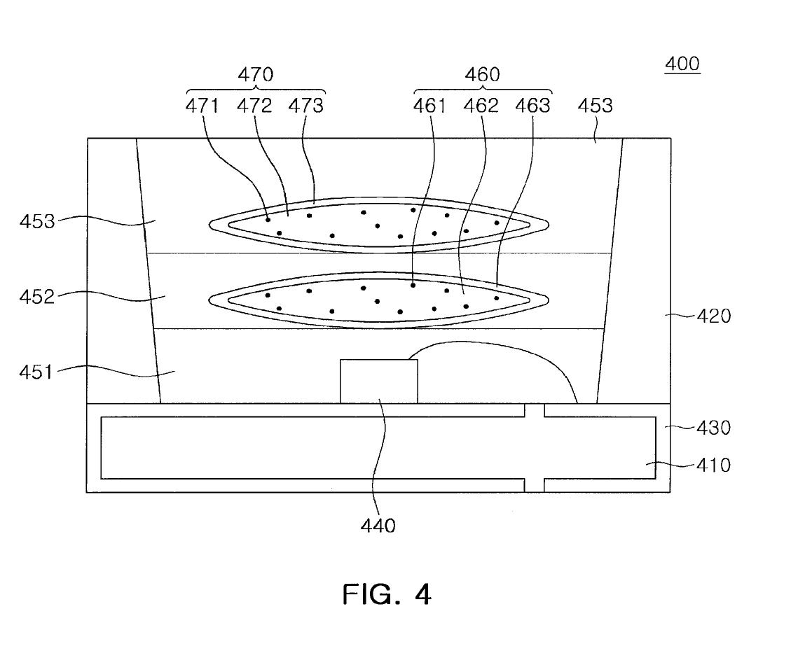

FIG. 4 illustrates a light emitting device including a quantum dot wavelength converter according to another exemplary embodiment of the invention. In the present embodiment, the light emitting device 400 includes a first quantum dot wavelength converter 460 and a second quantum dot wavelength converter 470. In the light emitting device 400 of FIG. 4, a supporter 410, an electrode part 430, a reflecting part 420, a light emitting source 440 and an encapsulating material function in an identical manner to those of the previous embodiment and thus will not be further described.

In the light emitting device 400 of the present embodiment, the quantum dot wavelength converter may include a plurality of quantum dot wavelength converters. Referring to FIG. 4, out of at least two quantum dot wavelength converters, one closer to the light emitting source 440 is referred to as the first quantum dot wavelength converter 460 and the other is referred to as the second quantum dot wavelength converter 470. The light emitting source 440, when mounted, is encapsulated with a first encapsulant 451, the first quantum dot wavelength converter 460 is disposed thereon and encapsulated with the second encapsulant 452. Then, the second quantum dot wavelength converter 470 is disposed on the second encapsulant 452 and encapsulated with a third encapsulant 453. The light emitting device including the at least two quantum dot wavelength converters can emit white light or light of various colors more easily.

Out of the plurality of quantum dot wavelength converters, at least two may include wavelength converting quantum dots different from each other. Therefore, the first quantum dot wavelength converter 460 may include first quantum dots 461 and the second quantum dot wavelength converter 470 may include second quantum dots 462. Here, the first and second quantum dots 461 and 462 can be wavelength-converted differently from each other. For example, when the light emitting source 440 emits blue light, the first quantum dot wavelength converter 460 emits red light and the second quantum dot wavelength converter 470 emits green light, the light emitting device may emit white light finally. Alternatively, when the light emitting source 440, the first quantum dot wavelength converter 460, and the second quantum dot wavelength converter 470 may emit a corresponding one of blue light, red light and green light, respectively, the light emitting device may emit white light eventually. Moreover, the first quantum dot wavelength converter 460 and the second quantum dot wavelength converter 470 may include a plurality of quantum dots each having an emission wavelength band different from one another.

Referring to FIG. 4, the light emitting device is illustrated to include two quantum dot wavelength converters, but may include, for example, three quantum dot wavelength converters. Therefore, in a different embodiment from the present embodiment, when the light emitting source emits an ultraviolet ray and the three quantum dot wavelength converters emit blue light, green light and red light, respectively, the light emitting device may emit white light finally. In addition, to produce the white light emitting device, in place of employing wavelength converting quantum dots of one color in the quantum dot wavelength converter, a phosphor may be added to the encapsulant to be utilized together with the quantum dot wavelength converter.

Referring to FIGS. 3 and 4, the light emitting devices each are configured as a package but not limited thereto. For example, the light emitting device may be formed of a lamp-type light emitting device.

As set forth above, according to exemplary embodiments of the invention, in a quantum dot wavelength converter, quantum dots are sealed as an undiluted solution without being purified. Accordingly, this precludes a need for an additional purifying process and prevents an emission wavelength band from being changed due to surface oxidation during purification of ligand.

In a method of manufacturing a quantum dot wavelength converter, a pack-type wavelength converter including quantum dots can be configured regardless of the size or kind of quantum dots. This allows the wavelength converter to be manufactured in a simple process and utilized conveniently in various fields. Moreover, density of quantum dots in a composite is determined by controlling density of the quantum dots used to thereby produce a high-density quantum dot composite.

Also, the quantum dot wavelength converter is used as a wavelength converter of light emitted from a light emitting source to ensure that a white light emitting device can be easily manufactured.

While the present invention has been shown and described in connection with the exemplary embodiments, it will be apparent to those skilled in the art that modifications and variations can be made without departing from the spirit and scope of the invention as defined by the appended claims.

1-8. (canceled)

9. A method of manufacturing a quantum dot wavelength converter, the method comprising:
dispersing a quantum dot wavelength-converting excitation light and generating a wavelength-converted light in a dispersive medium to prepare a wavelength converting part; and
sealing the wavelength converting part with a sealer,
wherein the quantum dot is dispersed in the dispersive medium in an undiluted liquid state without being purified after synthesis.

10. The method of claim 9, wherein the sealing comprises stacking first and second sealing sheets;
injecting the wavelength converting part into an area between the first and second sealing sheets; and
heating around and thermally adhering the wavelength converting part of the first and second sealing sheets.

11-18. (canceled)
